(19) United States
(12) Patent Application Publication
(10) Pub. No.: US 2026/0102753 A1
(43) Pub. Date: Apr. 16, 2026

(54) LIQUID ION GENERATOR AND METHOD OF PREPARING ION-METAL COMPLEX USING SAME

(71) Applicant: DeepWave, Inc., Santa Clara, CA (US)

(72) Inventors: Dae-kyu CHOI, Suwon-si (KR); Do-hyeong HAN, Suwon-si (KR)

(73) Assignees: NP Holdings America, Inc., Santa Clara, CA (US); DeepWave, Inc., Santa Clara, CA (US)

(21) Appl. No.: 18/914,876

(22) Filed: Oct. 14, 2024

(51) Int. Cl. B01J 19/08; H01J 37/08; H01J 37/317

(52) U.S. Cl. CPC B01J 19/088; H01J 37/08; H01J 37/3171; B01J 2219/0813; B01J 2219/0818; B01J 2219/0854

(57) ABSTRACT

Disclosed are a liquid ion generator and a method of preparing an ion-metal complex using the same. More particularly, the ion generator includes a chamber; an electromagnetic field generator for forming an electric field or a magnetic field in the chamber; and a power source for supplying power to the electromagnetic field generator.

### BACKGROUND OF THE INVENTION

### 1. Field of the Invention

The present disclosure relates to a liquid ion generator and a method of preparing an ion-metal complex using the same.

### 2. Description of the Related Art

Complexes of transition metals and ions are being utilized in a wide variety of fields. For example, complexes, i.e., ion-metal complexes, of transition metals and ions are being actively studied in the fields of catalysts, semiconductor materials, magnetic materials, batteries, etc.

Ion-metal complexes can be manufactured in various ways depending on the constituent elements. For example, there is a method of firing a metal precursor and ions in an oxygen atmosphere. However, this method has a problem in that it takes a long time to manufacture ion-metal complexes.

### SUMMARY OF THE INVENTION

The present disclosure has been made in view of the above problems, and it is an object of the present disclosure to provide a method of preparing an ion-metal complex, for example, an ion-metal complex oxide.

It is another object of the present disclosure to provide an ion generator that can be used in the preparation method.

It will be understood that technical problems of the present disclosure are not limited to the aforementioned problems and other technical problems not referred to herein will be clearly understood by those skilled in the art from disclosures below.

In accordance with the present disclosure, the above and other objects can be accomplished by the provision of an ion generator, including: a chamber; an electromagnetic field generator for forming an electric field or a magnetic field in the chamber; and a power source for supplying power to the electromagnetic field generator.

The power source may include one or more of AC power, variable AC power, DC power, variable DC power, and/or a combination thereof.

The power source may include at least one waveform of a sine wave, a square wave, or a pulse wave.

In some embodiments, the ion generator may further include a temperature controller for controlling a temperature inside the chamber.

The electromagnetic field generator may include a first electrode and second electrode at least partially facing each other.

In some embodiments, the ion generator may further include an electrode-moving element for controlling positions of the first and second electrodes, wherein the electrode-moving element includes one or more of a motor, a magnet, an electromagnet, and/or a combination thereof.

The number of the facing electrodes may be two or more, and the electrodes may be alternately arranged.

The electromagnetic field generator may further include a third electrode and a fourth electrode, and the ion generator may further include a rotating element for rotating at least a portion of the electromagnetic field generator, wherein the first electrode and the third electrode are rotated together by the rotating element, the second electrode and the fourth electrode are rotated together by the rotating element, wherein, in a certain rotation state, the first electrode and the second electrode at least partially face each other, wherein, in a certain rotation state, the third electrode and fourth electrode at least partially face each other, wherein the first electrode and the fourth electrode form an identical pole, and wherein the second electrode and the third electrode form an identical pole.

In some embodiments, the ion generator may further include a separation membrane for preventing an ion source from contacting the first or second electrode in the chamber.

The first electrode and the second electrode may be plated to prevent the first electrode and the second electrode from contacting an ion source in the chamber.

The electromagnetic field generator may include a coil at least partially wound thereon.

The electromagnetic field generator may further include a first electrode and second electrode facing each other in a direction of an induced magnetic field generated by the coil.

The power source may include: a first power source for supplying power to the coil, and a second power source for supplying power to the first electrode and the second electrode.

In accordance with another aspect of the present disclosure, there is provided a method of preparing an ion-metal complex, the method including: applying an electromagnetic field to a mixture of a precursor and ions so that the ions effectively penetrate, diffuse into, inject into, combine with, or coat the precursor.

The polarity of the electromagnetic field may be changed.

Specific details of other embodiments are included in the detailed description.

### BRIEF DESCRIPTION OF THE DRAWINGS

The above and other objects, features, and advantages of the present disclosure will be more clearly understood from the following detailed description taken in conjunction with the accompanying drawings, in which:

FIG. 1 illustrates a schematic diagram of an ion generator according to an embodiment of the present disclosure;

FIG. 2 is a flowchart illustrating a method of preparing an ion-metal complex according to an embodiment of the present disclosure;

FIG. 3 is a schematic diagram illustrating processes for performing the preparation method of FIG. 2 using the ion generator of FIG. 1;

FIG. 4 illustrates a schematic diagram of an ion generator according to another embodiment of the present disclosure;

FIG. 5 illustrates a schematic diagram of an ion generator according to still another embodiment of the present disclosure;

FIG. 6 illustrates a schematic diagram of an ion generator according to still another embodiment of the present disclosure;

FIG. 7 is a schematic diagram illustrating the movement of electrodes of the ion generator of FIG. 6;

FIG. 8 is a schematic diagram illustrating the movement of electrodes in an ion generator according to still another embodiment of the present disclosure;

FIG. 9 is a schematic diagram illustrating the movement of electrodes in an ion generator according to still another embodiment of the present disclosure;

FIG. 10 illustrates a schematic diagram of an ion generator according to still another embodiment of the present disclosure;

FIG. 11 illustrates a schematic diagram of an ion generator according to still another embodiment of the present disclosure;

FIG. 12 illustrates a schematic diagram of an ion generator according to still another embodiment of the present disclosure;

FIG. 13 illustrates a schematic diagram of an ion generator according to still another embodiment of the present disclosure;

FIG. 14 illustrates a schematic diagram of an ion generator according to still another embodiment of the present disclosure;

FIG. 15 illustrates a schematic diagram of an ion generator according to yet another embodiment of the present disclosure.

### DETAILED DESCRIPTION OF THE INVENTION

Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided to convey the concept of the disclosure to those skilled in the art.

Various changes may be made to embodiments presented in the present disclosure. Examples described below are not intended to limit embodiments of the present disclosure, and should be understood to include all modifications, equivalents, or alternatives thereto.

As used herein, the term “and/or” includes any and all combinations of one or more of the associated listed items. As used herein, the singular forms “a”, “an” and “the” are intended to include the plural forms as well, unless clearly stated otherwise. It will be further understood that the terms “comprises” and/or “comprising,” when used in this specification, specify the presence of stated components, but do not preclude the presence or addition of one or more other components. A numerical range expressed using “to” indicates a numerical range including values stated before and after “to” as the lower and upper limits. A numerical range expressed using “about” or “approximately” indicates a value or a numerical range within 20% of the value or the numerical range stated after “about”or “approximately”.

In this specification, ordinal modifiers such as “first component”, “second component”, “first-first component”, etc., when referring to components, are only used to distinguish one component from another. Therefore, the first component referred to below may be referred to as the second component within the scope of the technical idea of the present disclosure. For example, what is referred to as the first component in one embodiment may be referred to as the second component in another embodiment.

In the drawings, the present disclosure is not limited to the illustrated form and components may be enlarged or reduced in size, thickness, width, length, and the like.

Spatially relative terms, such as “above,” “upper,” “on,” “below,” “beneath,” “lower,” and the like, may be used herein for ease of description to describe one element or feature's relationship to another element(s) or feature(s) as illustrated in the figures. It will be understood that the spatially relative terms may encompass a different orientation of the device other than the orientation depicted in the figures. For example, if the device in the figures is turned over, elements described as “below” or “beneath” other elements or features would then be oriented “above”the other elements or features.

The first direction X means any direction on the plane, and the second direction Y means another direction intersecting or orthogonal to the first direction X within the plane. The third direction Z means another direction intersecting or perpendicular to the plane.

Hereinafter, the present disclosure is described in detail with reference to the accompanying drawings.

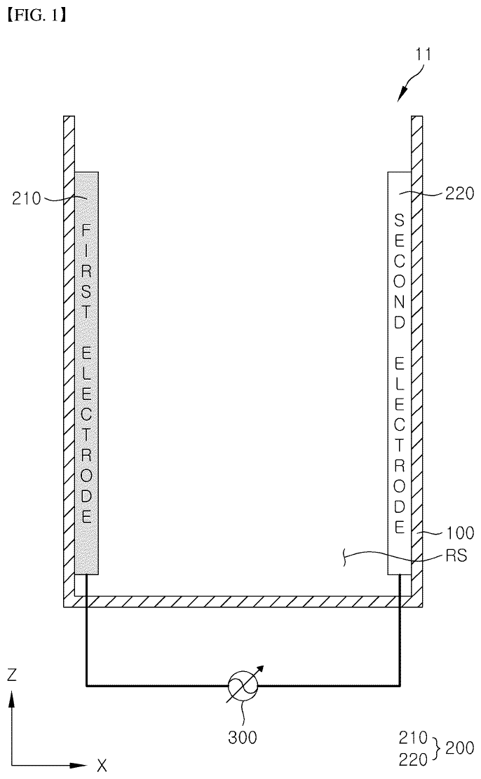

FIG. 1 illustrates a schematic diagram of an ion generator according to an embodiment of the present disclosure.

Referring to FIG. 1, a liquid ion generator 11 (or a device for manufacturing an ion-active material) according to the embodiment may include a chamber 100, and may further include an electromagnetic field generator 200 and a power source 300.

The chamber 100 may provide a reaction space RS into which reactants, e.g., a precursor and/or an ion source, are fed. The precursor may be a precursor including a transition metal or an iron phosphate metal compound. As a particular example, the precursor may include titanium, manganese, nickel, cobalt, iron, aluminum, phosphorus, and alloys of two or more thereof. The ion source may provide ions, e.g., cations, of atoms that physically/chemically bond with the precursor. The ion source is dissociated to provide a target ion of an ion-metal complex to be formed. In other words, the ion source may include a compound containing a target ion atom of an ion-metal complex to be formed. For example, when a lithium-metal complex is to be formed, an ion source may include a lithium compound. As a non-limiting example, the ion source may include one or more of lithium carbonate (Li₂CO₃), lithium hydroxide (LiOH), lithium nitrate (LiNO₃), lithium sulfide (Li₂S), lithium oxide (Li₂O), lithium phosphate (Li₃PO₄), lithium acetate (LiC₂H₃O₂), lithium fluoride (LiF), lithium nitride (Li₃N), and/or a mixture thereof.

The electromagnetic field generator 200 may form an electric field and/or a magnetic field in the reaction space RS inside the chamber 100. In this embodiment, the electromagnetic field generator 200 may include a first electrode 210 and second electrode 220 that face each other. The first electrode 210 and the second electrode 220 may be spaced apart from each other in a first direction X while facing each other in a state in which at least a portion of the reaction space RS is placed between the first electrode 210 and the second electrode 220.

In some embodiments, a plating layer (not shown) disposed on the surfaces of the first electrode 210 and/or the second electrode 220 may be further included. That is, both the first electrode 210 and the second electrode 220 may be subjected to plating treatment. As described below, the ion source may be dissociated to form ions, and the ions may move in the reaction space RS. Here, the plating layer may be provided to prevent ions from directly contacting and damaging the first electrode 210 and the second electrode 220. Elements of the plating layer may be appropriately selected in consideration of the elements contained in the ion source.

The power source 300 may provide power to the electromagnetic field generator 200, e.g., the first electrode 210 and the second electrode 220. The power source 300 may include one or more of AC power, variable AC power, DC power, variable DC power, and/or a combination thereof. Specifically, the power source 300 may provide AC power to the first electrode 210 and the second electrode 220. In addition, the power source 300 may have at least one waveform of a sine wave, a square wave, or a pulse wave. The frequency of the power source 300 is preferably 1 megahertz (Mhz) or less, and, for example, may range from about 60 Hz to 120 Hz.

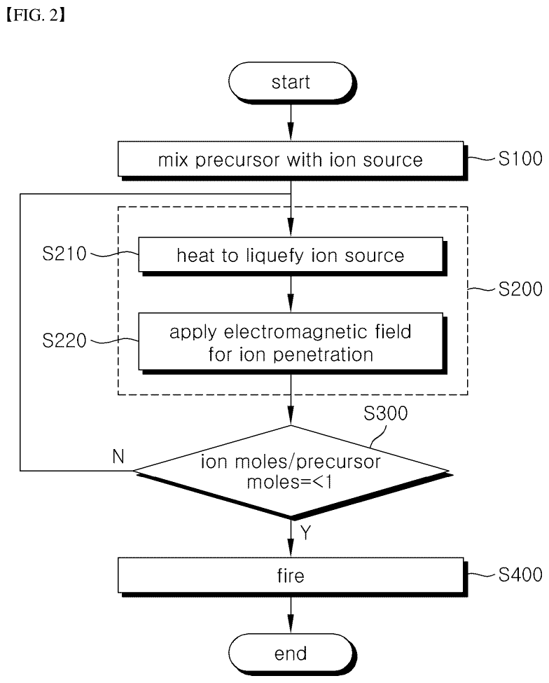

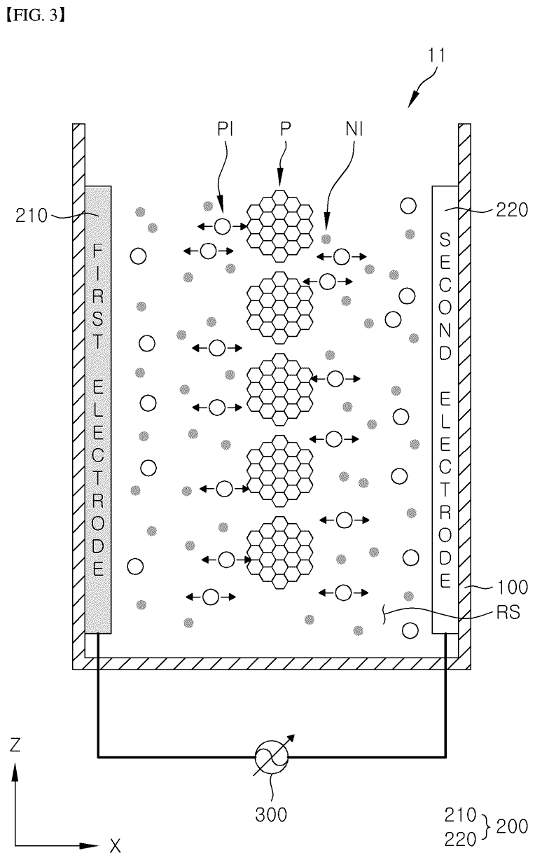

Although not shown in the drawings, the liquid ion generator 11 may further include a temperature controller (not shown) embedded in the chamber 100 or placed inside and/or outside the chamber 100. The temperature controller may include a heater for heating, etc. Hereinafter, a method of preparing the ion-metal complex or ion-active material according to an embodiment of the present disclosure is described in detail. FIG. 2 is a flowchart illustrating a method of preparing an ion-metal complex according to an embodiment of the present disclosure. FIG. 3 is a schematic diagram illustrating processes for performing the preparation method of FIG. 2 using the ion generator of FIG. 1.

Referring further to FIGS. 2 and 3, the method of preparing an ion-metal complex according to the embodiment may include a step S100 of mixing a precursor with an ion source; and an ion-generating step S200, and may further include a step S300 of determining an ion concentration; and a firing step S400.

First, the step S100 of mixing a precursor P with an ion source may be a step of preparing a mixture of a precursor and an ion source. The precursor P and the ion source have been described above. In addition, a solvent, etc., in addition to the precursor P and the ion source may be further mixed.

Also, although not shown in the drawing, the step S100 of preparing a mixture may further include mixing with a dopant. An example of the dopant may be one or more elements selected from Al, Ni, Co, Mn, Mg, Na, Si, Cr, Fe, Sr, V, Zn, W, Zr, B, Ba, Sc, Cu, Ti, Mo, P, F, Ga, Ge, As, Se, Br, Nb, Tc, Ta, Y, La, Ru, Sn, Sm, Ca, In, S, and a combination thereof.

In some embodiments, the step S100 of preparing a mixture of a precursor and an ion source may further include a step of heating only a precursor (not shown), and thus, may be a step of mixing an ion source with the heated precursor. The multi-particle nature and/or particle size of an ion-metal complex to be prepared may be controlled by selectively heating only the precursor before mixing the precursor with the ion source.

Next, the precursor P and ion source mixed in the chamber 100 may be ion-generated at S200. The ion-generating step S200 may be a step of forming ions, e.g., cations PI, derived from the ion source, and further effectively permeating, diffusing, injecting, combining, or coating the cations PI (or anions NI) into the precursor P.

The ion-generating step S200 may include a liquefaction step S210 of heating the mixture using a temperature controller, e.g., a heater, and at least partially dissolving, melting, or liquefying the ion source; and an electromagnetic field forming step S220 of forming an electromagnetic field.

In the liquefaction step S210, the heating temperature may be appropriately selected depending on the type of the ion source, but may be, for example, about 100° C. or higher, about 150° C. or higher, about 200° C. or higher, about 250° C. or higher, or about 300° C. or higher. An upper limit of the heating temperature is not particularly limited, but may be, for example, about 800° C. or lower, about 600° C. or lower, or about 500° C. or lower. In this step, the ion source, i.e., the compound, may be at least partially melted or dissolved to form cations PI and anions NI. When the ion source is a lithium-containing compound, formed cations PI may be lithium ions. Anions NI may vary depending on the type of lithium compound.

The time of the liquefaction step S210 may vary depending on the type of ion source and a heating temperature, but the liquefaction step S210 is preferably performed for several minutes.

In addition, in a state where at least some cations PI and anions NI are formed from the ion source, an electromagnetic field may be applied (S220). In the case where the first electrode 210 and the second electrode 220 facing each other are used as the electromagnetic field generator 200 as in the embodiment of FIG. 1, the polarity of the electric field formed in the reaction space RS may be alternately changed as AC power is applied to the first electrode 210 and the second electrode 220. Therefore, the ionized cations PI and anions NI in the reaction space RS may move within an electric field and collide with or contact the precursor P. In addition, heat may be generated according to the behaviors of the cations PI and the anions NI, and the melting or dissolution of the ion source may proceed further. As a non-limiting example, heating by means of a temperature controller, e.g., a heater, is not performed in the electromagnetic field forming step S220. In addition, the electromagnetic field forming step S220 may be performed for several minutes to several tens of minutes.

That is, the cations PI and anions NI may move due to the formed electromagnetic field and may effectively penetrate, diffuse into, inject into, combine with, or coat the inside or surface of the precursor P, so that the precursor P and the cations PI may form a physical/chemical bond. Thereby, the formation of an ion-metal complex may be induced.

Therefore, the ion-generating step S200 may satisfy preconditions for the firing step S400 within several minutes to several tens of minutes.

An upper limit of a distance between the first electrode 210 and the second electrode 220 may be about 10 cm, about 8.0 cm, about 6.0 cm, or about 5.0 cm. When the distance between the electrodes 210 and 220 is too large, the movement of ions according to the application of power (e.g., AC) may be minimal. A lower limit of the distance between the electrodes 210 and 220 is not particularly limited, but may be, for example, about 1.0 cm, about 1.5 cm, or about 2.0 cm.

The preparation method may control whether to start the subsequent process based on the concentration of the ions PI and NI and/or the concentration of the precursor P in the reaction space RS (S300). A determination step S300 may be performed by a controller (not shown) including a processor of the liquid ion generator 11. In an exemplary embodiment, the controller may perform the determination step S300 based on the concentration of cations PI (or the number of moles of cations) and the concentration of the precursor P (or the number of moles of a precursor) in the chamber 100.

Specifically, if the concentration of cations PI is not sufficiently low per determination step S300 after performing the ion-generating step S200, e.g., if the concentration of cations PI is greater than the concentration of the precursor P, the ion-generating step S200 may be performed again. On the other hand, if the concentration of the cations PI is sufficiently low, or the concentration of the precursor P is sufficiently high, e.g., if the concentration of the cations PI is less than or equal to the concentration of the precursor P, the firing step S400 may be performed. FIG. 2 illustrates a case in which the concentration of cations relative to the concentration of a precursor is compared with a numerical value of 1 (or weight, or reference value) in the determination step S300, but the present disclosure is not limited thereto. The numerical value (or weight, or reference value) to be compared may be appropriately adjusted.

The firing step S400 may be performed once or more. The respective firing step S400 is substantially performed in an oxygen atmosphere, and the firing temperature may be about 700° C. to 1,000°C, about 750° C. to 900° C., or about 800° C. to 850° C. The time of the process referred to as the firing step S400 may vary depending on the target to be fired, e.g., the precursor and the lithium compound. The process time may be in a range of about 10 minutes to 120 minutes, about 20 minutes to 90 minutes, or about 30 minutes to 60 minutes. Therefore, since the firing process time is significantly reduced compared to a conventional firing time of 12 hours or more, the energy, equipment, and cost for firing may be reduced.

The ion-metal complex formed in the ion-generating step S200 may form a stabilized ion-metal complex, such as an ion-metal complex oxide, by combining oxygen atoms in the firing step S400.

Although not shown in the drawings, a water treatment step and/or a grinding step may be further performed after the firing step S400.

According to this embodiment, at least some ions PI and NI may be formed through the liquefaction step S210, and heat may be generated due to the movement of the ions PI and NI in an electromagnetic field. Further, physical/chemical bonding between the precursor P and ions, particularly cations PI, may be effectively induced. In addition, a stabilized ion-metal complex may be formed through the firing step S400. According to an embodiment of the present disclosure, various ion-metal complexes or ion-metal complex oxides may be formed by changing the type of the precursor P and the type of ion source, i.e., the type of cations PI. For example, the prepared ion-metal complex may include one or more of Lithium Nickel Cobalt Manganese Oxide (NCM), Lithium Nickel Cobalt Aluminum Oxide (NCA), Lithium Nickel Cobalt Manganese (NCMX, doped with other metal X) Oxide, Lithium Iron Phosphate (LFP), Lithium Manganese Iron Phosphate (LMFP), Lithium Manganese Iron Phosphate (LMFPX, doped with other metal X), Lithium Titanate (LTO), Lithium Manganese Oxide (LMO), Lithium Nickel Manganese Oxide (LNMO), and Lithium Cobalt Oxide (LCO).

Hereinafter, other embodiments of the present disclosure are described. However, descriptions of configurations that are substantially the same or similar to the above-described embodiment are omitted, and these will be easily understood by those skilled in the art from the accompanying drawings.

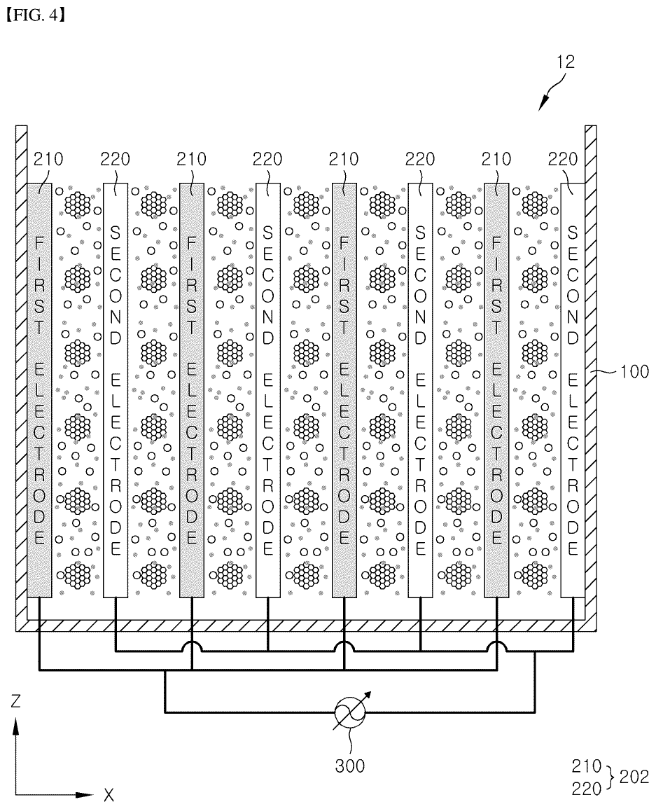

FIG. 4 illustrates a schematic diagram of an ion generator according to another embodiment of the present disclosure.

Referring to FIG. 4, a liquid ion generator 12 according to the embodiment includes a chamber 100, an electromagnetic field generator 202 and a power source 300; the electromagnetic field generator 202 includes one or more first electrodes 210 and second electrodes 220 that receive power of different polarities from the power source 300. Here, there is a difference from FIG. 1 in that the number of the first electrodes 210, the second electrodes 220, or both are two or more.

The plural first electrodes 210 and the plural second electrodes 220 may be arranged while alternately facing each other. Physical/chemical bonding between the precursor and the ions may be achieved more effectively by arranging the plural first electrodes 210 and the plural second electrodes 220 in one chamber 100.

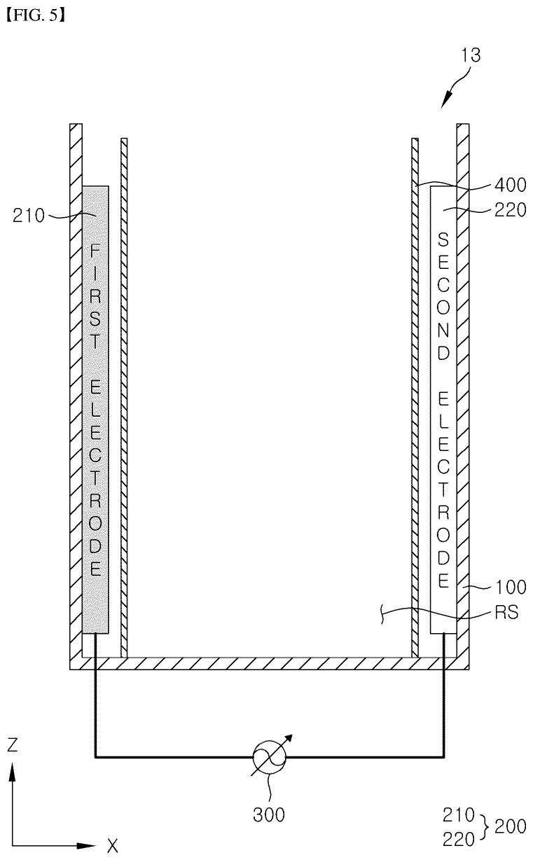

FIG. 5 illustrates a schematic diagram of an ion generator according to still another embodiment of the present disclosure.

Referring to FIG. 5, a liquid ion generator 13 according to this embodiment includes a chamber 100, an electromagnetic field generator 200 and a power source 300, and differs from FIG. 1 in that it further includes a separation membrane 400 (or a separation element, or a partition wall).

The separation membrane 400 may be located in the chamber 100. Specifically, the separation membrane 400 may partition the first electrode 210 and the second electrode 220 from a reaction space RS. Accordingly, this may prevent a precursor and/or an ion source and, further, cations and anions dissociated from an ion source, from contacting the first electrode 210 or the second electrode 220.

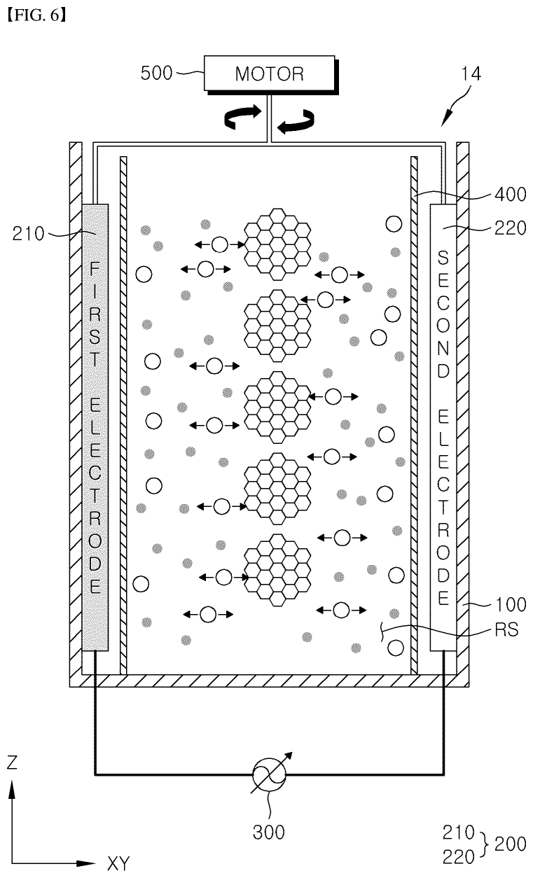

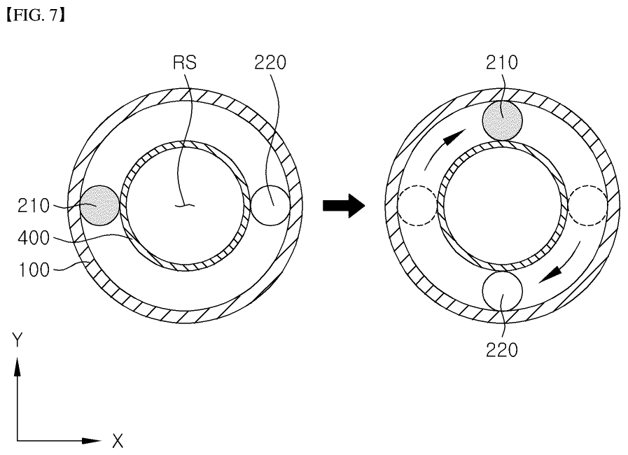

FIG. 6 illustrates a schematic diagram of an ion generator according to still another embodiment of the present disclosure. FIG. 7 is a schematic diagram illustrating the movement of electrodes of the ion generator of FIG. 6.

Referring to FIGS. 6 and 7, a liquid ion generator 14 according to this embodiment includes a chamber 100, an electromagnetic field generator 200, a power source 300 and a separation membrane 400, and differs from the embodiment of FIG. 5 in that it further includes an electrode-moving element 500.

The electrode-moving element 500 may change the physical position of the electromagnetic field generator 200, i.e., a first electrode 210 and/or a second electrode 220. The electrode-moving element 500 may include one or more of a motor, a magnet, an electromagnet, or a combination thereof.

In an exemplary embodiment, the chamber 100 may be provided in an approximately cylindrical shape in a planar view. In addition, the separation membrane 400 may be provided in an approximately cylindrical shape. Accordingly, the reaction space RS may have an approximately circular shape in a planar view, and the first electrode 210 and the second electrode 220 may be arranged in an annular compartment space.

The planar shape of the first electrode 210 and the second electrode 220 may be circular, but the present disclosure is not limited thereto. Based on the planar center of the chamber 100, the electrode-moving element 500 may rotate the first electrode 210 and the second electrode 220. Despite the rotation of at least one of the first electrode 210 and the second electrode 220, the first electrode 210 and the second electrode 220 may be spaced apart from each other while facing each other with the reaction space RS therebetween. As described above, ions may move due to an electric field formed between the first electrode 210 and the second electrode 220. The movement of ions may be further controlled by changing the positions of the first electrode 210 and the second electrode 220 as in this embodiment.

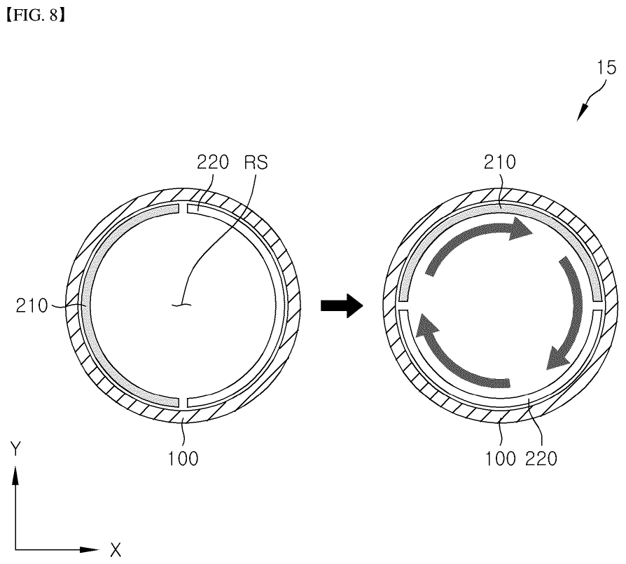

FIG. 8 is a schematic diagram illustrating the movement of electrodes in an ion generator according to still another embodiment of the present disclosure.

Referring to FIG. 8, a liquid ion generator 15 according to this embodiment includes a chamber 100, an electromagnetic field generator, a power source (not shown) and an electrode-moving element (not shown), and differs from the embodiment of FIG. 6 in that each of a first electrode 210 and second electrode 220 of the electromagnetic field generator is arc-shaped.

Based on the planar center of the chamber 100, the electrode-moving element may rotate the first electrode 210 and the second electrode 220.

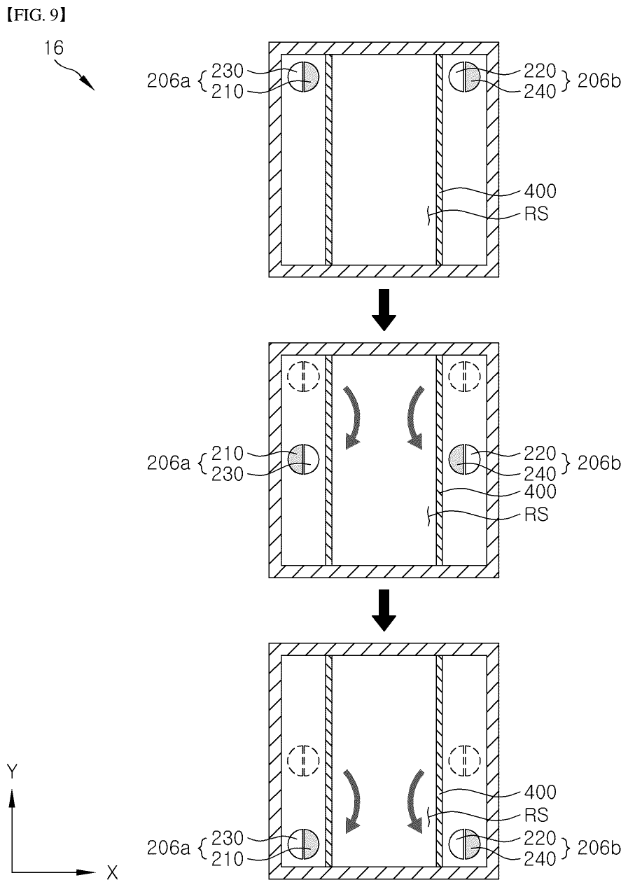

FIG. 9 is a schematic diagram illustrating the movement of electrodes in an ion generator according to still another embodiment of the present disclosure.

Referring to FIG. 9, a liquid ion generator 16 according to this embodiment includes a chamber 100, an electromagnetic field generator, a power source (not shown), a separation membrane 400 and an electrode-moving element (or a rotating element) (not shown), and differs from the embodiment of FIG. 6 in that the electromagnetic field generator further includes a third electrode 230 and a fourth electrode 240.

In an exemplary embodiment, in a planar view, the chamber 100 may be provided in an approximately square shape. In addition, a reaction space RS partitioned by the separation membrane 400 may have an approximately square shape.

The first electrode 210 and the third electrode 230 may be arranged adjacent to each other. For example, the first electrode 210 and the third electrode 230 may form one module 206a (or a first electrode assembly). Although not shown in the drawings, an insulator may be positioned between the first electrode 210 and the third electrode 230 to prevent short circuiting between the first electrode 210 and the third electrode 230.

In addition, the second electrode 220 and the fourth electrode 240 may be arranged adjacent to each other. For example, the second electrode 220 and the fourth electrode 240 may form one module 206b (or a second electrode assembly). Although not shown in the drawings, an insulator may be positioned between the second electrode 220 and the fourth electrode 240 to prevent short circuiting between the second electrode 220 and the fourth electrode 240.

When a power source (not shown) is an AC power source, power of different polarities may be applied to the first electrode 210 and the second electrode 220. In addition, power of different polarities may be applied to the first electrode 210 and the third electrode 230. In addition, power of the same polarity may be applied to the first electrode 210 and the fourth electrode 240. In other words, power of the same polarity may be applied to the second electrode 220 and the third electrode 230.

A space where a first electrode assembly 206a is arranged may be separated from a space where a second electrode assembly 206b is arranged. Specifically, the space where the first electrode assembly 206a is arranged and the space where the second electrode assembly 206b is arranged may be separated from each other with a reaction space RS therebetween.

The first electrode assembly 206a including the first electrode 210 and the third electrode 230 may be rotated together by the rotating element. In addition, the second electrode assembly 206b including the second electrode 220 and the fourth electrode 240 may be rotated together by the rotating element. Specifically, in a planar view, the first electrode assembly 206a may be revolved by the rotating element around the planar center thereof, and the second electrode assembly 206b may be revolved by the rotating element around the planar center thereof.

Further, the first electrode assembly 206a and the second electrode assembly 206b may be linearly moved by the electrode-moving element while being rotated by the rotating element. For example, the space where a first electrode assembly 206a is arranged and the space where the second electrode assembly 206b is arranged are respectively shaped to extend in a second direction Y, and the electrode-moving element may linearly move each of the first electrode assembly 206a and the second electrode assembly 206b in the second direction Y. For example, each of the first electrode assembly 206a and the second electrode assembly 206b may be linearly moved in the second direction Y.

The revolving and linear movement of the first electrode assembly 206a and the revolving and linear movement of the second electrode assembly 206b may be interrelated.

For example, in a certain rotational state where power of different polarities is applied to the first electrode 210 and the second electrode 220, the first electrode 210 and the second electrode 220 may face each other in the second direction Y. That is, in a state where the first electrode 210 is aligned toward the reaction space RS, the second electrode 220 may also be aligned toward the reaction space RS.

In addition, in a certain rotational state where power of different polarities is applied to the third electrode 230 and the fourth electrode 240, the third electrode 230 and the fourth electrode 240 may face each other in the second direction Y. That is, in a state where the third electrode 230 is aligned toward the reaction space RS, the fourth electrode 240 may also be aligned toward the reaction space RS.

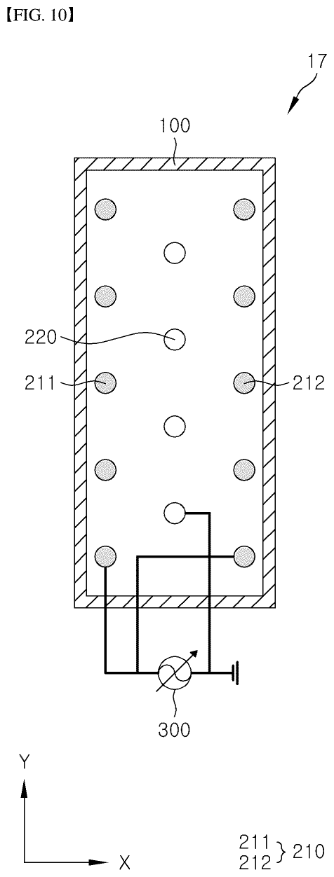

FIG. 10 illustrates a schematic diagram of an ion generator according to still another embodiment of the present disclosure.

Referring to FIG. 10, a liquid ion generator 17 according to this embodiment includes a chamber 100, an electromagnetic field generator, and a power source 300, and differs from the above-described embodiments in that the electromagnetic field generator includes first electrodes 210 and second electrodes 220, and the first electrodes 210 include 1-1 electrodes 211 and 1-2 electrodes 212.

In a planar view, each of the first electrodes 210 and the second electrodes 220 may have an approximately circular shape. For example, the first electrode 210 and the second electrode 220 may be rod-shaped extending in a third direction perpendicular to a plane to which a first direction X and a second direction Y belong.

Power of different polarities may be applied to the first electrodes 210 and the second electrodes 220. That is, at some time point, power of the same polarity may be applied to the 1-1 electrodes 211 and the 1-2 electrodes 212, and power of a different polarity from that of the first electrodes 210 may be applied to the second electrode 220.

The plural 1-1 electrodes 211 may be arranged in the second direction Y to form one electrode set (e.g., the 1-1 electrode set), and the plural 1-2 electrodes 212 may be arranged in the second direction Y to form one electrode set (e.g., a 1-2 electrode set). The 1-1 electrode set and the 1-2 electrode set may be spaced apart from each other approximately in the first direction X.

The plural second electrodes 220 may be arranged in the second direction Y to form one electrode set (e.g., a second electrode set). Here, the 1-1 electrode set and the 1-2 electrode set may be spaced apart from each other with the second electrode set therebetween in the first direction X.

In an exemplary embodiment, one 1-1 electrode 211 and one 1-2 electrode 212 may be spaced apart from each other while facing each other in the first direction X. On the other hand, one second electrode 220 may face the first electrodes 210 in a direction intersecting the first direction X and the second direction Y, not in the first direction X.

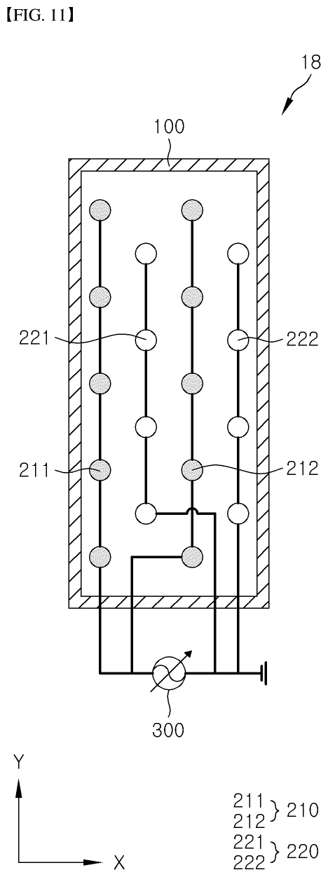

FIG. 11 illustrates a schematic diagram of an ion generator according to still another embodiment of the present disclosure.

Referring to FIG. 11, a liquid ion generator 18 according to this embodiment includes a chamber 100, an electromagnetic field generator and a power source 300, and differs from the embodiment of FIG. 10 in that the electromagnetic field generator includes first electrodes 210 and second electrodes 220, and the second electrodes 220 include 2-1 electrodes 221 and 2-2 electrodes 222.

As described above, in a planar view, each of the first electrodes 210 and the second electrodes 220 may have an approximately circular shape and a rod shape extending in a third direction. Power of different polarities may be applied to the first electrodes 210 and the second electrodes 220. That is, at some time point, power of the same polarity may be applied to the 1-1 electrodes 211 and the 1-2 electrodes 212, power of the same polarity may be applied to the 2-1 electrodes 221 and the 2-2 electrodes 222, and power of different polarities may be applied to the first electrodes 210 and the second electrodes 220.

The plural 1-1 electrodes 211 may be arranged in a second direction Y to form one electrode set (e.g., a 1-1 electrode set), and the plural 1-2 electrodes 212 may be arranged in the second direction Y to form one electrode set (e.g., a 1-2 electrode set). The 1-1 electrode set and the 1-2 electrode set may be spaced apart from each other approximately in a first direction X.

Similarly, the plural 2-1 electrodes 221 may be arranged in the second direction Y to form one electrode set (e.g., a 2-1 electrode set), and the plural 2-2 electrodes 222 may be arranged in the second direction Y to form one electrode set (e.g., a 2-2 electrode set). The 2-1 electrode set and the 2-2 electrode set may be spaced apart from each other approximately in the first direction X.

The 1-1 electrode set, 2-1 electrode set, 1-2 electrode set, and 2-2 electrode set described above may be sequentially arranged in the first direction X.

In an exemplary embodiment, one 1-1 electrode 211 and one 1-2 electrode 212 may be spaced apart from each other while facing each other in the first direction X. In addition, one 2-1 electrode 221 and one 2-2 electrode 222 may be spaced apart from each other while facing each other in the first direction X. On the other hand, one first electrode 210 and one second electrode 220 may face each other in a direction intersecting the first direction X and the second direction Y, without facing in the first direction X.

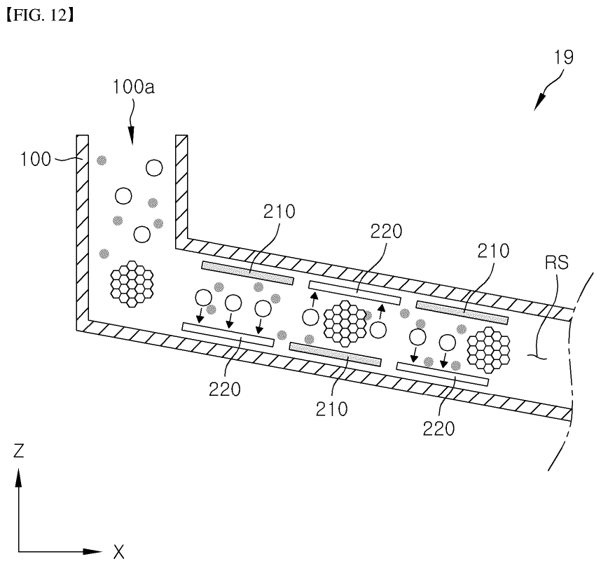

FIG. 12 illustrates a schematic diagram of an ion generator according to still another embodiment of the present disclosure.

Referring to FIG. 12, a liquid ion generator 19 according to this embodiment includes a chamber 100, an electromagnetic field generator and a power source (not shown), and differs from the above-described embodiments in that a reaction space RS inside the chamber 100 forms a downward slope so that reactants, e.g., a precursor and ion sources, physically move and an ion-generating step is performed.

The chamber 100 may include a reactant inlet 100a. A precursor and/or an ion source may be introduced into the reaction space RS through the reactant inlet 100a. The chamber 100 may provide a partially downwardly inclined space, e.g., a downwardly inclined part. The electromagnetic field generator including first electrodes 210 and second electrodes 220 may be placed in the downwardly inclined part of the chamber 100.

As described above, the first electrodes 210 and the second electrodes 220 may be at least partially opposite to each other. FIG. 12 illustrates a case where the first electrodes 210 and the second electrodes 220 are arranged on a ceiling of the downwardly inclined part of the chamber 100 and a bottom on a lower side thereof. In addition, the first electrodes 210 and the second electrodes 220 may be alternately arranged along the extension direction of the downwardly inclined part of the chamber 100. The angle of inclination (θ) of the downwardly inclined part with respect to a horizontal plane may be in a range of about 1°to 89°, or about 10°to 80°.

Although not shown in the drawings, the first electrodes 210 and the second electrodes 220 may be arranged on both side walls of the chamber 100 (e.g., in a Y direction).

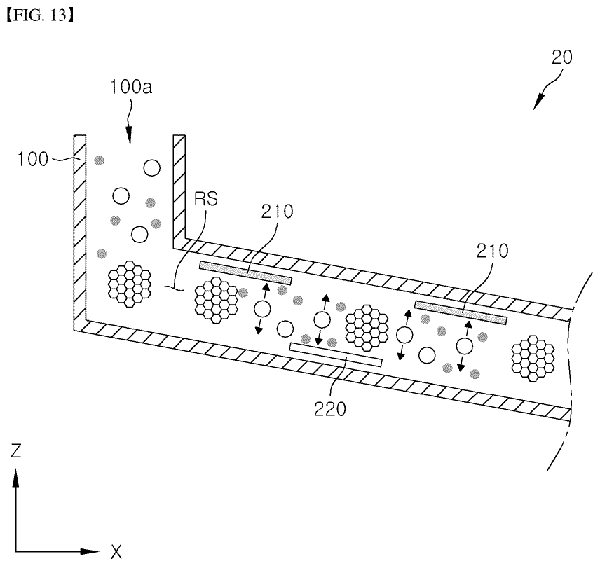

FIG. 13 illustrates a schematic diagram of an ion generator according to still another embodiment of the present disclosure.

Referring to FIG. 13, a liquid ion generator 20 according to this embodiment includes a chamber 100 for providing a reaction space RS, an electromagnetic field generator and a power source (not shown), and differs from the embodiment of FIG. 12 in that first electrodes 210 of the electromagnetic field generator are arranged on a ceiling of a downwardly inclined part and the second electrodes 220 are arranged on a bottom of the downwardly inclined part. As a non-limiting example, the first electrodes 210 may be arranged only on the ceiling of the downwardly inclined part, and the second electrodes 220 may be arranged only on the bottom of the downwardly inclined part.

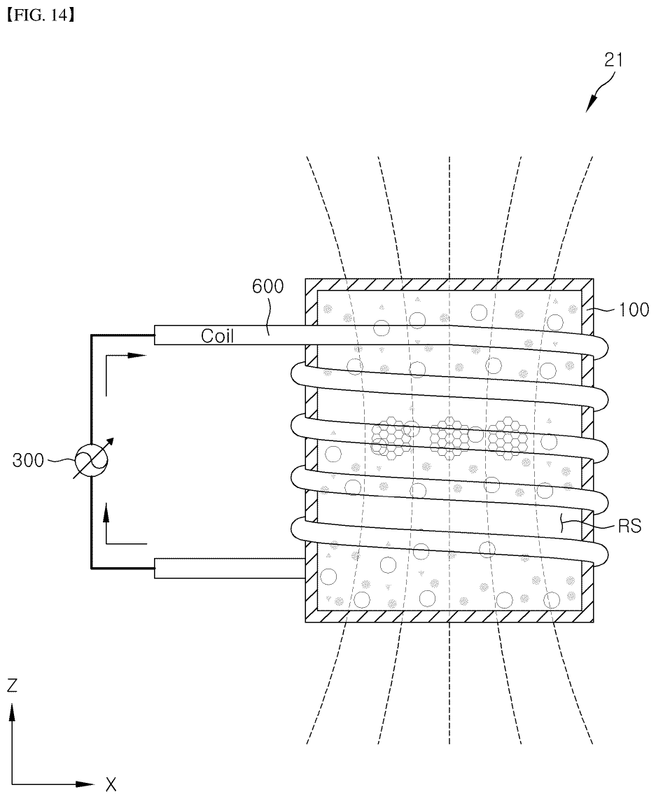

FIG. 14 illustrates a schematic diagram of an ion generator according to still another embodiment of the present disclosure.

Referring to FIG. 14, a liquid ion generator 21 according to this embodiment includes a chamber 100, an electromagnetic field generator and a power source 300 and differs from the embodiment of FIG. 1, etc. in that the electromagnetic field generator includes a wound coil 600 to generate a magnetic field.

The coil 600 may be arranged to at least partially surround the chamber 100. For example, the coil 600 may surround a reaction space RS inside the chamber 100. In addition, the power source 300 may supply power to the coil 600. The power source 300 has been described above.

When current flows through the coil 600, an induced magnetic field may be formed by the coil 600. With respect to the reaction space RS, the direction of the generated induced magnetic field may be approximately a third direction Z, but the present disclosure is not limited thereto.

As described above, the electromagnetic field generator including the coil 600 may form an electromagnetic field in the reaction space RS, and the polarity of the magnetic field may alternately change as AC power is applied. Accordingly, the ionized cations and anions in the reaction space RS move within the magnetic field and may collide with or contact the precursor. That is, the cations PI and anions NI may move due to the formed electromagnetic field and may effectively penetrate, diffuse into, inject into, combine with, or coat the inside or surface of the precursor P, so that the precursor and the ions may form a physical/chemical bond, thereby inducing the formation of an ion-metal complex.

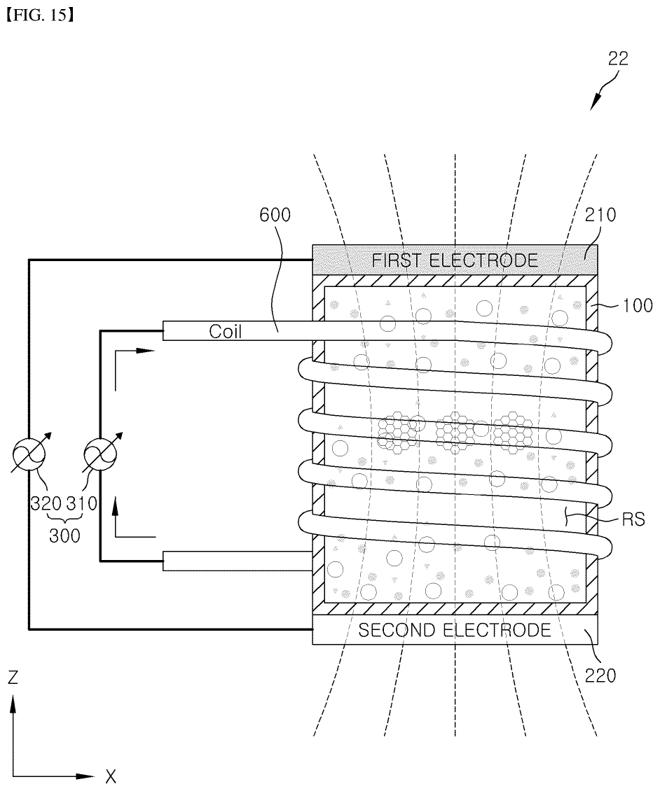

FIG. 15 illustrates a schematic diagram of an ion generator according to yet another embodiment of the present disclosure.

Referring to FIG. 15, a liquid ion generator 22 according to this embodiment includes a chamber 100; an electromagnetic field generator including a coil 600; and a power source 300, and differs from the embodiment of FIG. 14 in that the electromagnetic field generator further includes a first electrode 210 and a second electrode 220.

The liquid ion generator 22 according to the embodiment may include a coil 600 wound thereon, thereby forming an induced magnetic field. Further, the electromagnetic field generator may further include a first electrode 210 and second electrode 220 facing each other in a third direction Z. The first electrode 210 and the second electrode 220 may be arranged to face each other in the direction of an induced magnetic field generated by the coil 600 (e.g., the third direction Z).

The power source 300 may include a first power source 310 and a second power source 320. The first power source 310 may supply power to the coil 600, and the second power source 320 may supply power to the first electrode 210 and the second electrode 220. The first power source 310 and the second power source 320 may be substantially the same as the power sources described above, so a duplicate description is omitted.

In accordance with the embodiments of the present disclosure, ions having a charge in an electromagnetic field can collide with or contact a metal precursor, so that the ions can effectively penetrate, diffuse into, inject into, combine with, or coat the inside or surface of the metal precursor.

The effects according to the embodiments of the present disclosure are not limited to the contents exemplified above.

Although the preferred embodiments have been described above, they are merely examples and not intended to limit any embodiments and it should be appreciated that various modifications and applications not described above may be made by one of ordinary skill in the art without departing from the embodiments.

Therefore, it should be understood that the scope of the present disclosure includes changes, equivalents or substitutes of the technical concept described above. For example, each component specifically shown in the embodiment of the present disclosure may be modified and implemented. In addition, it should be understood that differences related to these modifications and applications are within the scope of the present disclosure.

What is claimed is:

1. An ion generator, comprising:
a chamber;
an electromagnetic field generator for forming an electric field or a magnetic field in the chamber; and
a power source for supplying power to the electromagnetic field generator.

2. The ion generator according to claim 1, wherein the power source comprises one or more of AC power, variable AC power, DC power, variable DC power, or a combination thereof.

3. The ion generator according to claim 2, wherein the power source comprises at least one waveform of a sine wave, a square wave, or a pulse wave.

4. The ion generator according to claim 1, further comprising a temperature controller for controlling a temperature inside the chamber.

5. The ion generator according to claim 1, wherein the electromagnetic field generator comprises a first electrode and second electrode at least partially facing each other.

6. The ion generator according to claim 5, further comprising an electrode-moving element for controlling positions of the first and second electrodes,
wherein the electrode-moving element comprises one or more of a motor, a magnet, an electromagnet, or a combination thereof.

7. The ion generator according to claim 5, wherein the number of the facing electrodes is two or more, and the electrodes are alternately arranged.

8. The ion generator according to claim 5, wherein the electromagnetic field generator further comprises a third electrode and a fourth electrode, and
the ion generator further comprises a rotating element for rotating at least a portion of the electromagnetic field generator,
wherein the first electrode and the third electrode are rotated together by the rotating element,
the second electrode and the fourth electrode are rotated together by the rotating element,
wherein, in a certain rotation state, the first electrode and the second electrode at least partially face each other,
wherein, in a certain rotation state, the third electrode and fourth electrode at least partially face each other,
wherein the first electrode and the fourth electrode form an identical pole, and
wherein the second electrode and the third electrode form an identical pole.

9. The ion generator according to claim 4, further comprising a separation membrane for preventing an ion source from contacting the first or second electrode in the chamber.

10. The ion generator according to claim 5, wherein the first electrode and the second electrode are plated to prevent the first electrode and the second electrode from contacting an ion source in the chamber.

11. The ion generator according to claim 1, wherein the electromagnetic field generator comprises a coil at least partially wound thereon.

12. The ion generator according to claim 11, wherein the electromagnetic field generator further comprises a first electrode and second electrode facing each other in a direction of an induced magnetic field generated by the coil.

13. The ion generator according to claim 12, wherein the power source comprises:
a first power source for supplying power to the coil, and
a second power source for supplying power to the first electrode and the second electrode.

14. A method of preparing an ion-metal complex, the method comprising: applying an electromagnetic field to a mixture of a precursor and ions so that the ions effectively penetrate, diffuse into, inject into, combine with, or coat the precursor.

15. The method according to claim 14, wherein a polarity of the electromagnetic field is changed.
